(19) United States
(12) Patent Application Publication
(10) Pub. No.: US 2009/0236132 A1
(43) Pub. Date: Sep. 24, 2009

(54) ORGANIC/INORGANIC HYBRID COMPOSITION WITH ELECTROSTATIC DISCHARGE PROTECTION PROPERTY

(75) Inventors: Ming-Tsung Hong, Sanchong City (TW); Shur-Fen Liu, Hsinchu County (TW); Jinn-Shing King, Hsinchu County (TW)

Correspondence Address: PAI PATENT & TRADEMARK LAW FIRM, 1001 FOURTH AVENUE, SUITE 3200, SEATTLE, WA, 98154, US

(73) Assignee: INDUSTRIAL TECHNOLOGY RESEARCH INSTITUTE, Hsinchu County (TW)

(21) Appl. No.: 12/243,934

(22) Filed: Oct. 1, 2008

(30) Foreign Application Priority Data
Mar. 20, 2008 (TW) 097109807

(51) Int. Cl. H05K 1/09; C08G 59/00; H01B 1/12; H01B 1/02; C08K 5/1515

(52) U.S. Cl. 174/257; 524/612; 252/500; 252/519.33; 524/114

(57) ABSTRACT

An organic/inorganic hybrid composition with electrostatic discharge protection properties, high thermal stability, good adhesion, low costs, and good processability is disclosed. The composition includes a thermosetting resin system, an inherently dissipative polymer, and non-insulating particles. The inherently dissipative polymer and the non-insulating particles are dispersed within the thermosetting resin system.

### CROSS REFERENCE TO RELATED APPLICATIONS

This Application claims priority of Taiwan Patent Application No. 097109807, filed on Mar. 20, 2008, the entirety of which is incorporated by reference herein.

### BACKGROUND OF THE INVENTION

1. Field of the Invention

The invention relates to electrostatic discharge protection technology and more particularly to an organic/inorganic hybrid composition with electrostatic discharge protection property.

2. Description of the Related Art

In recent years, concurrent with the trend to develop smaller, lighter, and more portable electronic products, the requirement for increased functions and dimensional stability has increased. Thus, integrated circuit (IC) fabrication with narrow fine pitches, lower working voltages and higher working frequencies have been developed. Accordingly, because conventional circuit layout techniques for nanochips with line widths less than 65 nm cannot provide appropriate electrostatic discharge (ESD) protection, IC carriers with ESD protection have been provided. The current method used for IC carriers with ESD protection is to solder an ESD protection component on a surface of the IC carrier. Additionally, driven by industry trends, packaging integrity of ICs has increased, and single device dimensions have dramatically shrunk. As a result, often, there is not enough available space on IC packages and carriers for an appropriate amount (thousands) of surface mount technology (SMT) type ESD protection components.

Typical ESD protection components are integrated on ICs or substrates by soldering or SMT technology. The main material in the ESD protection components are inorganic materials. ESD protection materials, with mainly organic inner frameworks materials, are called polymeric variable voltage materials (VVMs). VVM polymeric variable resistors are widely utilized. The polymeric VVMs comprise polymer resin with additives of conductive particles/semiconductor particles/insulating particles or non-conductive particles. The polymeric VVMs are insulating materials with large resistance when applied with a common voltage. Meanwhile, the polymeric VVMs become electrically conductive with low resistance when ESD occurs, to conduct and disperse high voltage; thus, protecting circuit components from damage.

Karen P. et al. discloses single and multi-layered variable voltage protection devices in U.S. Pat. No. 5,807,509, wherein the polymers in the materials thereof are fluorosilicone rubber and polydimethylsiloxane, the conductive powders are aluminum, and the semiconductor powders are aluminum oxide with some additives of insulating powders, such as fumed silica. Two kinds of structures are disclosed in U.S. Pat. No. 5,807,509, wherein one comprises a plurality of material layers with different powder compositions without conductive layers therebetween, and the other comprises a plurality of material layers with different powder compositions with conductive layers therebetween, and laminated layer numbers and powder compositions can be modified to achieve ESD protection performance. Further, disclosures in U.S. Pat. No. 6,310,752, U.S. Pat. No. 6,373,719, U.S. Pat. No. 6,657,532, US 2005/0052811, and U.S. Pat. No. 7,049,926 relate to ESD protection component process and structural designs. The disclosure in U.S. Pat. No. 6,251,513 also relates to ESD protection component structural designs. The materials disclosed in U.S. Pat. No. 6,251,513 are mixtures of organic polymers and powders with different properties, wherein the polymers are mainly thermoplastic polymers such as polyester, and various kinds of conductive/semiconductor/insulating powders are disclosed. In the former published US 2003/0218851, US 2003/0025587, US 2003/0071245, US 7,132,922, US 2003/0071245 discloses the introduction of VVMs during the printed circuit board (PCB) process, and the VVMs are utilized during the mass production process of ESD protection components. In U.S. Pat. No. 7,132,922, conductive/semiconductor/insulating powders are utilized in a core-shell structure, or other elements are doped in a core-shell structure. The described arts disclose different compositions of VVMs, and mainly disclose different structural designs and application types. More importantly, the described arts only relate to SMT type ESD protection component technologies.

Meanwhile, U.S. Pat. No. 5,409,968, U.S. Pat. No. 5,476,714, U.S. Pat. No. 5,669,381, and U.S. Pat. No. 5,781,395 disclose technologies relating to polymeric VVMs, but they are only applied in SMT type components. For the materials disclosed in the art, the basic starting point for an ESD protection mechanism, is formation of a path to transmit electrons utilizing powders with different properties and different diameters stacked in polymers. The materials are insulating materials with large resistance when applied with a common voltage. Meanwhile, the materials become electrically conductive with low resistance when ESD occurs, to conduct and disperse the high voltage through the path; thus, protecting the electronic components and circuits from damage. Regarding the material recipe, however, the disclosures only describe mixtures of polymers and conductive/semiconductor/insulating powders.

### BRIEF SUMMARY OF THE INVENTION

Given the aforementioned, a substrate material with electrostatic discharge (ESD) protection properties that is compatible with current PCB process technologies is needed. The substrate material should comprise ESD protection properties, high thermal resistance, good adhesion, low costs, and good mechanical properties.

As such, an embodiment of the invention is disclosed, providing an organic/inorganic hybrid material of the dielectric composition with ESD protection properties, high thermal resistance, improved adhesion, lower costs, and better processability. The composition includes a thermosetting resin system, an inherently dissipative polymer, and non-insulating powders. The inherently dissipative polymer and the non-insulating powders are dispersed in the thermosetting resin system.

Further scope of the applicability of the invention will become apparent from the detailed description given hereinafter. It should be understood, however, that the detailed description and specific examples, while indicating preferred embodiments of the invention, are given by way of illustration only, as various changes and modifications within the spirit and scope of the invention will become apparent to those skilled in the Art from this detailed description.

A detailed description is given in the following embodiments.

### BRIEF DESCRIPTION OF THE DRAWINGS

none

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

An organic/inorganic hybrid material of the dielectric composition with electrostatic discharge (ESD) protection properties of a preferred embodiment of the invention comprises three main parts; that is, a thermosetting resin system, an inherently dissipative polymer, and non-insulating particles. The inherently dissipative polymer and the non-insulating particles are dispersed in the thermosetting resin system.

The mixture comprising the thermosetting resin system, the inherently dissipative polymer, and the non-insulating particles is preferably substantially uniform. The thermosetting resin system is a mixture comprising a thermosetting resin, a hardener, a catalyst, a polymeric softening agent, and a dispersant, and preferably a substantially uniform mixture.

In one embodiment, the inherently dissipative polymer preferably comprises at least one functional group selected from a group consisting of OH⁻, NH₂⁻, NHR⁻, COOH⁻, and anhydride. In another embodiment, the inherently dissipative polymer is preferably selected from a group consisting of oligomers, polymers, and a combination thereof, and the molecular weight range thereof is preferably between 100 and 100000. The oligomers can be an epoxy oligomer comprising an acrylic group, or other suitable oligomers. The polymers can be polyethers, such as polyethylene oxide (PEO), polypropylene oxide (PPO), and etc. with inherently dissipative properties. In yet another embodiment, the weight of the inherently dissipative polymer is between 10% and 30% of that of the thermosetting resin system.

The thermosetting resin is preferably selected from a group consisting of epoxy, phenolic resin, and a combination thereof. The epoxy is preferably selected from a group consisting of multi functional epoxy, bisphenol A type epoxy, cycloaliphatic epoxy, naphthalene containing epoxy, diphenylene epoxy, novolac epoxy, and a combination thereof. The multi functional epoxy can be the epoxy shown in Equation (1) below, for example. The bisphenol A type epoxy can be diglycidyl ether of bisphenol A epoxy (DGEBA epoxy or BADGE epoxy) or tetrabromo bisphenol A diglycidyl ether epoxy, for example. The cycloaliphatic epoxy can be dicyclopentadiene epoxy, for example. The novolac epoxy can be phenol novolac epoxy or O-cresol novolac epoxy, for example.

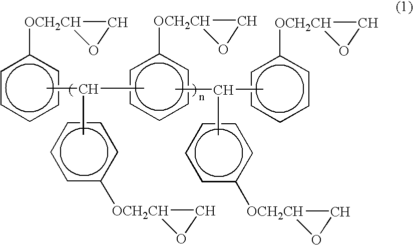

The hardener is preferably selected from a group consisting of diamine, phenol resin, anhydride, and a combination thereof. An exemplary structural formula of the diamine is shown in the Equation (2) as follows:

H₂N—R₁—NH₂ (2).

R₁ can be aryl, aliphatic, cycloaliphatic, or silane containing aliphatic, such as:

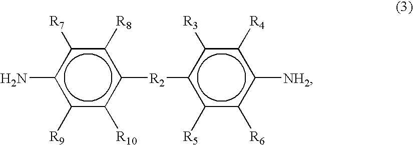

wherein R₂ is preferably selected from a group consisting of X, CH₂, SO₂, O, S, and C(CH₃)₂, and R₃ through R₁₀ are preferably selected from a group consisting of H, CH₃, C₂H₅, C₃H₇, and C(CH₃)₃.

The phenol resin is phenol based resin, naphthol based resin, terpene phenol resin, dicyclopentadiene resin, 1,1,1-Tris(4-hydroxyphenyl)ethane (or called 4,4′,4″ ethylidene trisphenol), tetra phenylolethane, tetraxylenol ethane, and tetracresololethane, for example. The terpene phenol resin can be selected from a group consisting of Equations (4) through (6) as follows:

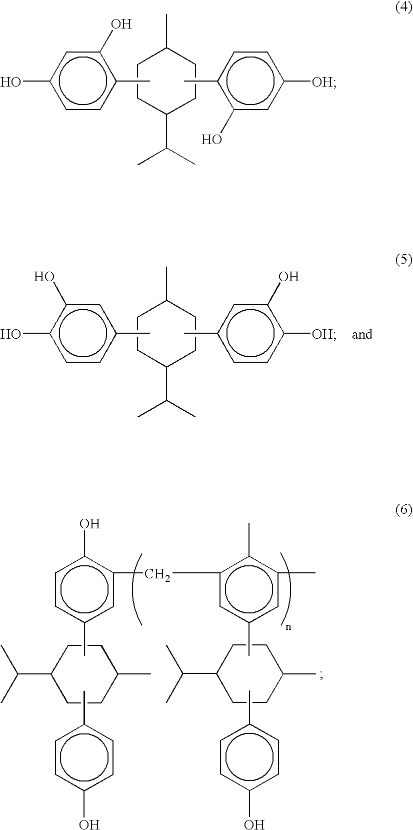

The catalyst can be selected from a group consisting of trifluoroboron complex, tertiary amine, metal hydroxides, a monocyclic oxide coordinated anionic catalyst, and imidazole, for example. The trifluoroboron complex is a cation-series catalyst, and can be selected from a group consisting of RNH₂.BF₃, R₂NH.BF₃, R₃N.BF₃, and etc. The tertiary amine, metal hydroxides, a monocyclic oxide coordinated anionic catalyst, are anion-series catalysts, and can be selected from a group consisting of R₃N, N,N,N,N-tetramethyl guanidine (TMG), and NCH₂C—C(NH)—N(CH₃)₂, for example. The imidazole can be selected from a group consisting of 1-methylimidazole, 1,2-dimethylimidazole, 2-heptadecylimidazole, and 2-ethyl-4-methylimidazole.

The dispersant can be selected from a group consisting of copolyesteramide, polyester, and a combination thereof The dispersant had good adhesion with the non-insulating particles, and had good compatibility and some reactivity with the organic resins when experimented on. Accordingly, thermal resistance and reliability of the substrate utilizing the inventive organic/inorganic hybrid material of the dielectric composition with electrostatic discharge protection property was improved. In one embodiment, the content of the dispersant in the thermosetting resin system is 30 wt % or less.

In one embodiment, the thermosetting resin system may comprise insulating particles therein, and the content of the insulating particles in the thermosetting resin system is preferably less than 10 wt %. Further, the insulating particles are selected from a group consisting of fumed silica, aluminum oxide, calcium carbonate, and a combination thereof, for example.

In yet another embodiment, the thermosetting resin system may further comprise a polymeric softening agent selected from a group consisting of polyester, polyamide, polyamide-imide, polyvinyl Butyral, synthetic rubber, polycaprolactone (PCL, R—[—O[—CO(CH₂)₅—O—]ₙ—]_{f}), aliphatic eopxy resin, carboxyl-terminated butadiene/acrylonitrile (CTBN), and a combination thereof, and the content of the polymeric softening agent in the thermosetting resin system is preferably 30 wt % or less.

The non-insulating particles can be electrically conductive particles, electrically conductive particles/semiconductor particles, or electrically conductive particles/semiconductor particles/insulating particles.

The particle sizes of the non-insulating particles are between nanometer scales and micrometer scales. Further, the volume ratio of the non-insulating particles in the organic/inorganic hybrid material of the dielectric composition with electrostatic discharge protection property is between 10 vol % and 50 vol %. Moreover, the shapes of the electrically conductive particles are selected from a group consisting of a round shape, an acicular shape, a clavate shape, a shell-core structure, and an irregular shape.

In one embodiment, the electrically conductive particles can be selected from at least one of the group consisting of nickel, cobalt, graphite, gold, aluminum, barium, carbon black, copper, iron, silver, zinc, palladium, and tin. In another embodiment, the electrically conductive particles may comprise two groups of materials, wherein one is metal or a material comprising metallic properties, such as the one selected from at least one of a group consisting of nickel, cobalt, graphite, gold, aluminum, barium, copper, iron, silver, zinc, palladium, and tin, and the other is carbon black. In yet another embodiment, the electrically conductive particles, such as the one selected from at least one of a group consisting of nickel, cobalt, gold, aluminum, barium, copper, iron, silver, zinc, palladium, and tin, and the semiconductor particles can be selected from a group consisting of oxides of metal of the electrically conductive particles, oxides of metal alloy of the electrically conductive particles, and metal-doped oxides of metal of the electrically conductive particles.

Further, some additives, such as silane coupling agent, can be optionally added in the organic/inorganic hybrid material of the dielectric composition with electrostatic discharge protection property of the preferred embodiment of the invention. The silane coupling agent can be selected from a group consisting of aminosilane, epoxysilane, and a combination thereof The silane coupling agent is utilized as a diluent and an adhesion promoter.

Other additives, which may be optionally added in the organic/inorganic hybrid material of the dielectric composition with electrostatic discharge protection property of the preferred embodiment of the invention, may comprise at least one of the additives shown in Equations (7) through (12) as follows:

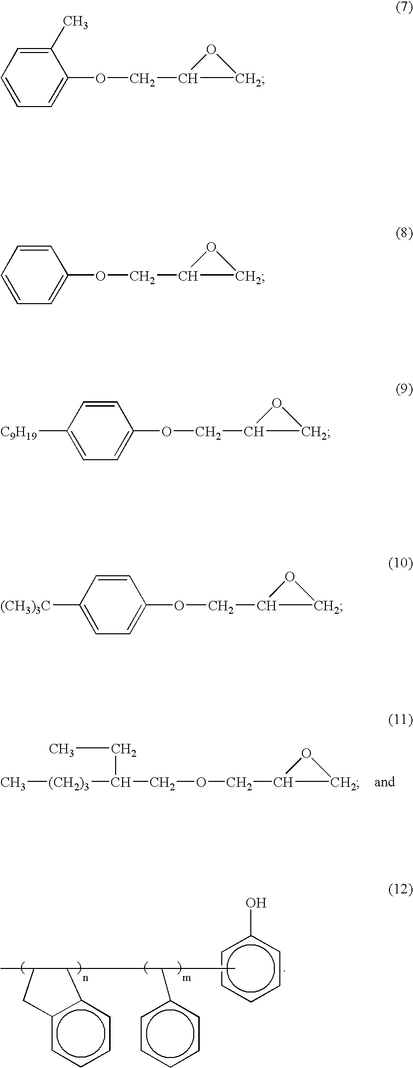

Next, an exemplary fabrication method of the organic/inorganic hybrid material of the dielectric composition with electrostatic discharge protection property of the preferred embodiment of the invention is described.

First, a thermosetting resin and an inherently dissipative polymer are properly selected from the described examples with optimum volumes, and a suitable solvent, such as selecting dimethylformamide (DMF) depending on the selected materials. The determined thermosetting resin, inherently dissipative polymer, and solvent are disposed in a reactor and heated to a temperature of between 90° C. and 95° C., completely dissolving the thermosetting resin and the inherently dissipative polymer in the solvent. Next, a suitable catalyst (such as the one selected from the aforementioned catalysts) is disposed in the solution. Thereafter, the solution is heated to a temperature of between 100° C. and 140° C., and allowed to react for between 2 hours and 6 hours, and then cooled.

Next, a suitable hardener, selected from the previously described, depending on the selected thermosetting resin and inherently dissipative polymer, with a optimum volume, is added in the solution and completely dissolved. Then, a suitable dispersant, selected from the described examples depending on the selected thermosetting resin and inherently dissipative polymer with a optimum volume, is added in the solution, and simultaneously, a suitable polymeric softening agent and other additives (such as the one selected from the described examples) with optimum volumes can be optionally added in the solution.

Next, suitable non-insulating particles selected from the described examples, with optimum volumes as required, can be added in the solution, and simultaneously, suitable insulating particles (such as the one selected from the described examples) with optimum volumes can be optionally added in the solution. After addition of all the particles, the solution is stirred with a high rotational speed, making the solution uniform, completing the organic/inorganic hybrid material of the dielectric composition with electrostatic discharge protection property of the preferred embodiment of the invention.

The organic/inorganic hybrid material of the dielectric composition with electrostatic discharge protection property of the preferred embodiment of the invention is preferably disposed in a ball mill, and mixed and dispersed for a period of between 12 hours and 36 hours in order to make sure all compositions therein are substantially uniformly mixed. Thus, completing a well dispersed coating liquid of the organic/inorganic hybrid material of the dielectric composition with electrostatic discharge protection property.

Next, a process for fabricating a circuit substrate utilizing the organic/inorganic hybrid material of the dielectric composition with electrostatic discharge protection property of the preferred embodiment of the invention is described. The processing circuit substrate can be utilized as a printed circuit board (PCB) or an IC (in a semiconductor chip) carrier.

In one embodiment, the organic/inorganic hybrid material of the dielectric composition with electrostatic discharge protection property of the preferred embodiment of the invention is formed on a copper foil by a coating step, forming a resin coated copper foil (RCC). The resin coated copper foil is then thermally laminated with another copper foil under vacuum, curing the organic/inorganic hybrid material of the dielectric composition with electrostatic discharge protection property between the copper foils, thus completing the circuit substrate. At this time, the cured organic/inorganic hybrid material of the dielectric composition with electrostatic discharge protection property of the preferred embodiment of the invention has become a dielectric layer of the circuit substrate.

In another embodiment, the organic/inorganic hybrid material of the dielectric composition with electrostatic discharge protection property of the preferred embodiment of the invention is formed on an upper copper foil by a coating step, thus forming an upper resin coated copper foil. The same organic/inorganic hybrid material of the dielectric composition with electrostatic discharge protection property as previously mentioned is formed on a lower copper foil by a coating step; thus forming a lower resin coated copper foil. Next, the upper copper foil is stacked on the organic/inorganic hybrid material of the dielectric composition with electrostatic discharge protection property on the lower copper foil. Then, the upper and lower resin coated copper foils are thermally laminated under vacuum, curing the organic/inorganic hybrid materials of dielectric composition with electrostatic discharge protection property on the upper and lower resin coated copper foils, completing the circuit substrate. At this time, the cured organic/inorganic hybrid materials of dielectric composition with electrostatic discharge protection property of the preferred embodiment of the invention have become a first dielectric layer (between the upper and lower copper foils) and a second dielectric layer (on the upper copper foil) of the circuit substrate.

After completing the fabrication of the circuit substrate, an electrical property measurement was performed on the dielectric layers. The results showed that the dielectric constant under a frequency of 1 MHz, was between 20 and 40, the dissipation factor was between 0.1 and 0.2, and the trigger voltage was between 10V and 350V. Further, regarding the thermal property measurement, all of the dielectric layers passed the soldering resistance test under 288° C. Moreover, adhesion strength measurement of the dielectric layers and the copper foils attached thereon was performed. The results showed that the adhesion strengths were all greater than 5 lb/in.

The compositions of the dielectric layers formed by the organic/inorganic hybrid material of the dielectric composition with electrostatic discharge protection property of the preferred embodiment of the invention respectively comprise:

1. a suitable thermosetting epoxy resin system selected from the aforementioned examples;

2. an added inherently dissipative polymer selected from the aforementioned examples which can be reactive with epoxy;

3. non-insulating particles with particle sizes between nanometer scales and micrometer scales selected from the aforementioned examples, and optionally added insulating particles, wherein the electrically conductive particles are necessary, resulting in the dielectric layers to become electrically conductive with low resistance when ESD occurs (instantaneous high voltage applied), and capable of comprising both ESD protection properties and improved processability to guarantee the quality of the substrate materials;

4. a dispersant selected from the aforementioned examples, capable of improving the thermal resistance (dispersants with lower molecular weigh may cause low thermal resistance of the resulting substrate). Specifically, the soldering resistance of the substrate increases and reliability is substantially increased during product applications; and

5. an optionally added polymeric softening agent or other additives to further adjust the substrate processability and the adhesion between the dielectric layers and the conductive layers.

Thus, a substrate with ESD protection properties is fabricated by the described exemplary process utilizing the complete organic/inorganic hybrid material of the dielectric composition with electrostatic discharge protection property, wherein the organic/inorganic hybrid material of the dielectric composition with electrostatic discharge protection property becomes a dielectric layer, such as an interlayer dielectric layer, of the substrate, the trigger voltage of the dielectric layer can be controlled to be between 10V and 350V, and the dielectric layer has outstanding adhesion with a copper foil (the adhesion strength between the dielectric layer and the copper foil is greater than 5 lb/in).

### EXPERIMENT EXAMPLES AND COMPARATIVE EXAMPLE

First, the organic/inorganic hybrid materials of dielectric composition with electrostatic discharge protection property of a Comparative Example 1 and Experiment Examples 1 through 5 were fabricated. Every Comparative Example and Experiment Example had different compositions as shown in Table 1 listed below.

For the compositions listed in Table 1, the epoxy was diglycidyl ether of bisphenol A, tetrabromo bisphenol A diglycidyl ether epoxy, cycloaliphatic epoxy, multi functional epoxy, or a combination thereof. The polymers/oligomers were the described inherently dissipative polymers, such as an epoxy oligomer comprising an acrylic group, polyethylene oxide, polypropylene oxide, and etc. The hardener was diamine or phenol resin, for example. The catalyst and the dispersant were respectively selected from the aforementioned examples. The polymeric softening agent was selected from a group consisting of polyvinyl butyral (PVB) and carboxyl-terminated butadiene/acrylonitrile (CTBN). Regarding the non-insulating particles, the electrically conductive particles A were nickel particles with a particle sized of approximately 100 nm, the electrically conductive particles B were carbon black with a particle size of approximately 60 nm, and the semiconductor particles were zinc oxide particles with a particle size of approximately 20 nm. The insulating particles were silicon dioxide particles. The powder content in Table 1 was the total of the electrically conductive particles A, the electrically conductive particles B, the semiconductor particles, and the insulating particles. The “vol %” in the parenthesis means the volume percentage of the powder of the total described particles in the organic/inorganic hybrid materials of dielectric composition with electrostatic discharge protection property in the Comparative Example 1 and the Experiment Examples 1 through 5.

Regarding the fabrication methods of the organic/inorganic hybrid materials of dielectric composition with electrostatic discharge protection property of the Comparative Example 1 and the Experiment Examples 1 through 5, they respectively followed the quantities of every composition listed in Table 1. First, the epoxy and the polymers/oligomers were disposed in a reactor, and then dimethylformamide (DMF) with an optimum volume was added into the reactor, acting as a solvent. Thereafter, the reactor was heated to a temperature of between 90° C. and 95° C. to completely dissolve the epoxy and the polymers/oligomers, forming a solution. Next, the catalyst was added into the solution, and then the solution was heated to a temperature of between 100° C. and 140° C., reacting for a period of between 2 hours and 6 hours. Next, the hardener was added into the solution and was completely dissolved therein. Next, the dispersant and the polymeric softening agent were added into the solution. The solution was cooled to room temperature after the dispersant and polymeric softening agent was completely dissolved therein. Thereafter, the electrically conductive particles A, the electrically conductive particles B, the semiconductor particles, and the insulating particles were added into the solution. The solution was stirred by a high speed mixing agitator to form a uniform hybrid solution.

Next, the hybrid solutions of the Comparative Example 1 and the Experiment Examples 1 through 5 were respectively disposed in ball mills and continuously mixed and dispersed for a period of between 12 hours and 36 hours, forming well dispersed coating liquids of the organic/inorganic hybrid materials of dielectric composition with electrostatic discharge protection property of the Comparative Example 1 and the Experiment Examples 1 through 5.

Then, the coating liquids of the organic/inorganic hybrid materials of dielectric composition with electrostatic discharge protection property of the Comparative Example 1 and the Experiment Examples 1 through 5 were respectively applied to copper foils by squeegees, and then heated to remove the solvent, partially curing the coating liquids of the organic/inorganic hybrid materials of dielectric composition with electrostatic discharge protection property to form the so-called resin coated copper foils. Next, the resin coated copper foils were respectively thermally laminated with copper foils (at approximately 200° C. for 2.5 hours), hardening the resin coated copper foils. Thus, the organic/inorganic hybrid materials of dielectric composition with electrostatic discharge protection property of the Comparative Example 1 and the Experiment Examples 1 through 5 respectively became the interlayer dielectric layers of the copper foil circuit substrates. Finally, the physical properties of the interlayer dielectric layers were measured, and the results are listed in Table 2.

TABLE 1

| | Comparative | Experiment | Experiment | Experiment | Experiment | Experiment |
|---|---|---|---|---|---|---|
| Composition (g) | Example 1 | Example 1 | Example 2 | Example 3 | Example 4 | Example 5 |
| Epoxy resin | 24 | 22.24 | 19.55 | 22.24 | 22.24 | 22.24 |
| system | | | | | | |
| IDP polymers/ | 0 | 1.76 | 4.45 | 1.76 | 1.76 | 1.76 |
| oligomers | | | | | | |
| dispersant | 7.2 | 7.2 | 7.2 | 4.5 | 4.5 | 4.5 |
| polymeric | 1.75 | 1.75 | 1.75 | 1.75 | 1.75 | 1.75 |
| softening agent | | | | | | |
| electrically | 18 | 18 | 18 | 22.5 | 22.5 | 22.5 |
| conductive | | | | | | |
| particles A | | | | | | |
| electrically | 0 | 0 | 0 | 0 | 0.048 | 0.12 |
| conductive | | | | | | |
| particles B | | | | | | |
| semiconductor | 54 | 54 | 54 | 22.5 | 22.5 | 22.5 |
| particles | | | | | | |
| insulating | 0 | 0 | 0 | 1.2 | 1.2 | 1.2 |
| particles | | | | | | |
| Powder content | 30 | 30 | 30 | 20 | 20 | 20 |
| (vol %) | | | | | | |

TABLE 2

| | Comparative | Experiment | Experiment | Experiment | Experiment | Experiment |
|---|---|---|---|---|---|---|
| Properties | Example 1 | Example 1 | Example 2 | Example 3 | Example 4 | Example 5 |
| Dielectric | 34.48 | 65.17 | 63.21 | 21.55 | 22.71 | 33.59 |
| constant | | | | | | |
| (1 Mz) | | | | | | |
| dissipation | 0.1230 | 0.1370 | 0.1540 | 0.0989 | 0.092 | 0.155 |
| factor (1 Mz) | | | | | | |
| Trigger | 184~236 | 10~100 | 50~120 | 135~190 | ~145 | 35~90 |
| voltage (V) | | | | | | |
| leakage | 1.57~3.12 m | 1.7~11.2 m | 8.6~26.3 m | 43~470μ | 25~457μ | 3.6~21 m |
| current (A) | | | | | | |
| Peeling | 4.8 | 5.1 | <4.5 | 5.5 | 5.5 | 5.6 |
| strength | | | | | | |
| (lb/in) | | | | | | |
| Processability | good | good | good | good | good | good |
| of the circuit | | | | | | |
| substrate | | | | | | |

Test parameters: tᵣᵢₛₑ = 2.2638 ms (0~7 V), pulse width = 71.02 ms

According to the measured dielectric properties of the Comparative Example 1 and the Experiment Examples 1 and 2, when an inherently dissipative polymer was added into the material compositions, the dielectric constants and the dissipation factors of the fabricated dielectric layers increased, and the trigger voltages of the dielectric layers decreased. This is because the properties of the inherently dissipative polymers increased the polarity and decreased the inner resistance of the total thermosetting resin system. Thus, increasing ESD protection effects, but not negatively affecting the processability of the circuit substrates.

For the Experiment Example 2, the weight percentage of the inherently dissipative polymer added in the resin system increased to 30 wt %. The difference in the dielectric layer properties from those of the Experiment Example 1 was limited, but the dissipation factor slightly increased. The thermoplastic property of the inherently dissipative polymer lowered the peeling strength between the copper foil and the dielectric layer, but still matched the needed processability of the circuit substrate.

Comparing the Experiment Example 1 and the Experiment Examples 3 through 5, the total powder content added in the organic/inorganic hybrid material of the dielectric composition with electrostatic discharge protection property of the Experiment Example 1 was higher (30 vol %), and the dielectric constant, dissipation factor, and leakage current of the fabricated dielectric layer was higher. Specifically, the higher leakage current for the Experiment Example 1 made ESD protection stability slightly worse than those of the fabricated dielectric layers in the Experiment Examples 3 through 5, and the peeling strength of the dielectric layer in the Experiment 1 was also worse. According to the physical properties of the dielectric layers in the Experiment Example 3 through 5, a decrease in the powder content (20 vol %) of the organic/inorganic hybrid material of the dielectric composition with electrostatic discharge protection property and an increase in the insulating particles and a few electrically conductive particles B, can adjust the ESD protection properties of the fabricated dielectric layers for achieving good processablity.

While the invention has been described by way of example and in terms of preferred embodiment, it is to be understood that the invention is not limited thereto. To the contrary, it is intended to cover various modifications and similar arrangements (as would be apparent to those skilled in the Art). Therefore, the scope of the appended claims should be accorded the broadest interpretation so as to encompass all such modifications and similar arrangements.

What is claimed is:

1. An organic/inorganic hybrid composition with electrostatic discharge protection property, comprising:
a thermosetting resin system;
an inherently dissipative polymer comprising at least one functional group selected from a group consisting of OH⁻, NH₂⁻, NHR⁻, COOH⁻, and anhydride; and
non-insulating particles, wherein the inherently dissipative polymer and the non-insulating particles are dispersed in the thermosetting resin system.

2. The composition as claimed in claim 1, wherein the thermosetting resin system is a mixture comprising a thermosetting resin, a hardener, a catalyst, and a dispersant.

3. The composition as claimed in claim 1, wherein the thermosetting resin system further comprises a polymeric softening agent.

4. The composition as claimed in claim 1, wherein the inherently dissipative polymer is selected from a group consisting of oligomers, polymers, and any combination thereof.

5. The composition as claimed in claim 1, wherein the thermosetting resin system comprises insulating particles therein, and the content of the insulating particles in the thermosetting resin system is 10 wt % or less.

6. The composition as claimed in claim 3, wherein the polymeric softening agent is selected from a group consisting of polyester, polyamide, polyamide-imide, polyvinyl Butyral, synthetic rubber, polycaprolactone (PCL, R—[—O[—CO(CH₂)₅—O—]ₙ—]_{f}), aliphatic epoxy resin, carboxyl-terminated butadiene/acrylonitrile (CTBN), and any combination thereof, and the content of the polymeric softening agent in the thermosetting resin system is 30 wt % or less.

7. The composition as claimed in claim 2, wherein the dispersant is selected from a group consisting of copolyester-amide, polyester, and any combination thereof, and the content of the dispersant in the thermosetting resin system is 30 wt % or less.

8. The composition as claimed in claim 2, wherein the thermosetting resin is selected from a group consisting of epoxy, phenolic resin, and any combination thereof.

9. The composition as claimed in claim 1, wherein the weight of the inherently dissipative polymer is between 10% and 30% of that of the thermosetting resin system.

10. The composition as claimed in claim 4, wherein the inherently dissipative polymer is selected from a group consisting of polymeric polyethers, an epoxy oligomer comprising an acrylic group, and a combination thereof, and the molecular weight range of the inherently dissipative polymer is between 100 and 100000.

11. The composition as claimed in claim 1, wherein:
the non-insulating particles are electrically conductive particles, electrically conductive particles/semiconductor particles, or electrically conductive particles/semiconductor particles/insulating particles;
the particle sizes of the non-insulating particles are from nanometer to micrometer scales; and
the volume percentage of the non-insulating particles in the organic/inorganic hybrid composition with electrostatic discharge protection property is between 10 vol % and 50 vol %.

12. The composition as claimed in claim 11, wherein the electrically conductive particles are selected from at least one of the group consisting of nickel, cobalt, graphite, gold, aluminum, barium, carbon black, copper, iron, silver, zinc, palladium, tin and any combination thereof.

13. The composition as claimed in claim 11, wherein the electrically conductive particles comprise carbon black and at least one of nickel, cobalt, graphite, gold, aluminum, barium, copper, iron, silver, zinc, palladium, and tin.

14. The composition as claimed in claim 11, wherein the shapes of the electrically conductive particles are selected from a group consisting of a sphere, a needle, a rod, a core-shell structure, and any irregular shapes.

15. The composition as claimed in claim 11, wherein the electrically conductive particles are metal, and the semiconductor particles are selected from a group consisting of metal oxide, metal alloy oxide, doped-metal oxide, and any combination thereof.

16. The composition as claimed in claim 15, wherein the shapes of the semiconductor particles are selected from a group consisting of a sphere, a needle, a rod, a core-shell structure, and any irregular shapes.

17. The composition as claimed in claim 5, wherein the insulating particles are selected from a group consisting of fumed silica, aluminum oxide, calcium carbonate, and any combination thereof.

18. The material as claimed in claim 2, wherein the hardener is selected from a group consisting of diamine, phenol resin, anhydride, and any combination thereof.

19. The material as claimed in claim 8, wherein the epoxy resin is selected from a group consisting of multi functional epoxy, bisphenol A type epoxy, cycloaliphatic epoxy, naphthalene containing epoxy, diphenylene epoxy, novolac epoxy, and any combination thereof.

20. The composition as claimed in claim 1, further comprising an additive selected from at least one of equation (A) through (F):

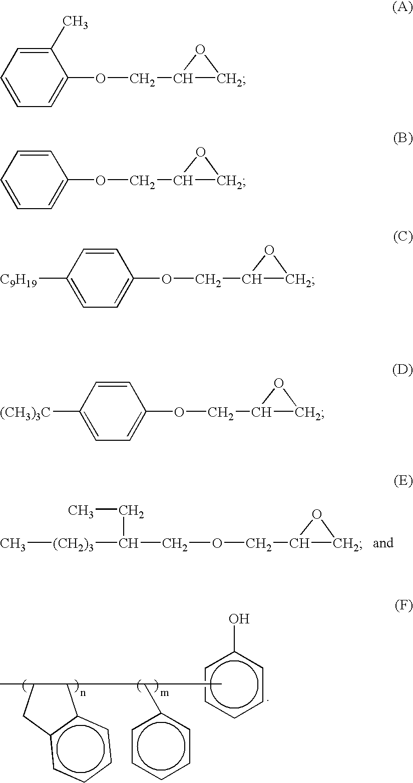

21. The composition as claimed in claim 1, further comprising a silane coupling agent selected from a group consisting of aminosilane, epoxysilane, and any combination thereof.

22. The composition as claimed in claim 2, wherein the catalyst is selected from a group consisting of trifluoroboron complex, tertiary amine, metal hydroxides, monocyclic oxide coordinated anionic catalyst, and imidazole.

23. The composition as claimed in claim 1, wherein a dielectric layer formed by thermal lamination of the organic/inorganic hybrid composition with electrostatic discharge protection property is disposed between two copper foils to complete a circuit board substrate.

24. The substrate as claimed in claim 23, wherein the trigger voltage of the dielectric layer is between 10V and 350V.

25. The substrate as claimed in claim 23, wherein the circuit board substrate is applied to a printed circuit board or an IC carrier.
